(19) United States
(12) Patent Application Publication
(10) Pub. No.: US 2026/0243834 A1
(43) Pub. Date: Aug. 20, 2026

(54) APPARATUS AND METHOD FOR TESTING CAPACITY OF BATTERY CELL

(71) Applicant: SK On Co., Ltd., Seoul (KR)

(72) Inventors: Byung Wook KIM, Daejeon (KR); Jung Hak YOON, Daejeon (KR); Woo Seop KIM, Daejeon (KR); Yu Gyung KIM, Daejeon (KR); Jung Uk KIM, Daejeon (KR); Ji Won HONG, Daejeon (KR)

(21) Appl. No.: 19/461,722

(22) Filed: Jan. 28, 2026

(30) Foreign Application Priority Data
Feb. 17, 2025 (KR) 10-2025-0020205

(51) Int. Cl. G01R 31/382; G01R 31/374; G01R 31/392; G01R 31/396

(52) U.S. Cl. CPC G01R 31/382; G01R 31/374; G01R 31/392; G01R 31/396

(57) ABSTRACT

A device for testing a capacity of a battery cell includes a charging/discharging unit charging and discharging a plurality of battery cells included in each of a plurality of trays, a capacity measurement unit measuring charge and discharge capacity of each of the plurality of battery cells based on a charge current a discharge current of the and charging/discharging unit, a temperature acquisition unit acquiring a temperature of each of the plurality of trays using a temperature of at least one battery cell among the plurality of battery cells, and a capacity consistency determination unit estimating a correction capacity for each of the plurality of battery cells, based on the charge capacity, the discharge capacity, and the temperature, and using different capacity correction formulas predetermined for the plurality of respective trays, and determining capacity consistency for each of the plurality of battery cells based on the correction capacity.

### CROSS-REFERENCE TO RELATED APPLICATION(S)

This patent document claims the priority and benefits of Korean Patent Application No. 10-2025-0020205 filed on Feb. 17, 2025, the disclosure of which is incorporated herein by reference in its entirety.

### TECHNICAL FIELD

The disclosure and implementations disclosed in this patent document generally relate to a device and method for testing capacity of a battery cell.

### BACKGROUND

Typically, during the battery formation process, there is a process of estimating capacity by charging and discharging battery cells. This capacity estimation process applies a correction formula to each of a plurality of trays each including a plurality of battery cells, thereby estimating the capacity.

In existing capacity estimation methods, capacity is estimated for single- and two-stage trays. For example, the same capacity correction formula is used to estimate battery cell capacity for both single- and two-stage trays.

However, with the recent increase in the number of battery cells processed simultaneously, additional trays have been added beyond the single- and two-stage trays. This results in more trays stacked than before, resulting in different temperature conditions for respective trays. Therefore, existing capacity estimation methods, which apply the same correction formula to all trays, cannot accurately estimate battery cell capacity.

### SUMMARY

The present disclosure can be implemented in some embodiments to provide a device and method for testing a capacity of a battery cell, in which a pre-prepared correction formula may be applied to each of a plurality of trays including a plurality of battery cells during a process of measuring and correcting capacity during charging and discharging of the battery cell.

In some embodiments of the present disclosure, a device for testing a capacity of a battery cell includes a charging/discharging unit charging and discharging a plurality of battery cells included in each of a plurality of trays; a capacity measurement unit measuring a charge capacity and a discharge capacity of each of the plurality of battery cells based on a charge current and a discharge current of the charging/discharging unit; a temperature acquisition unit acquiring a temperature of each of the plurality of trays using a temperature of at least one battery cell among the plurality of battery cells; and a capacity consistency determination unit estimating a correction capacity for each of the plurality of battery cells, based on the charge capacity, the discharge capacity, and the temperature, and using different capacity correction formulas predetermined for the plurality of respective trays, and determining capacity consistency for each of the plurality of battery cells based on the correction capacity.

The capacity measurement unit may be configured to include a charge capacity measurement unit measuring the charge capacity of each of the plurality of battery cells for the plurality of respective trays, based on the charge current from the charging/discharging unit; and a discharge capacity measurement unit measuring the discharge capacity of each of the plurality of battery cells for the plurality of respective trays, based on the discharge current from the charging/discharging unit.

The temperature acquisition unit may be configured to include a temperature sensor unit including at least one temperature sensor disposed to measure a temperature of a preset battery cell among the plurality of battery cells for the plurality of respective trays; and a temperature calculation unit calculating a temperature of each of the plurality of trays, based on a temperature measured by the temperature sensor unit.

The capacity consistency determination unit may be configured to include a capacity estimation unit estimating a correction capacity for each of the plurality of battery cells for the plurality of respective trays by applying the charge capacity, the discharge capacity, and the temperature to each of the plurality of battery cells for the plurality of respective trays using the capacity correction formulas for the plurality of respective trays; and a pass/fail determination unit comparing the correction capacity with a preset reference capacity range and determining whether each of the plurality of battery cells for the plurality of respective trays is good or bad based on a comparison result.

In some embodiments of the present disclosure, a method of testing a capacity of a battery cell includes charging and discharging a plurality of battery cells included in each of a plurality of trays; measuring a charge capacity and a discharge capacity of each of the plurality of battery cells based on a charge current and a discharge current of a charging/discharging unit; acquiring a temperature of each of the plurality of trays using a temperature of at least one battery cell among the plurality of battery cells; and a capacity consistency determination operation of estimating a correction capacity of each of the plurality of battery cells based on the charge capacity, the discharge capacity, and the temperature, and using different capacity correction formulas predetermined for the plurality of respective trays, and determining capacity consistency of each of the plurality of battery cells based on the correction capacity.

The measuring the charge capacity and the discharge capacity may be configured to include at least one of a charge capacity measurement operation of measuring the charge capacity of each of the plurality of battery cells for the plurality of respective trays, based on the charge current from the charging/discharging unit; and a discharge capacity measurement operation of measuring the discharge capacity of each of the plurality of battery cells for the plurality of respective trays, based on the discharge current from the charging/discharging unit.

The acquiring the temperature may be configured to include at least one of a temperature sensing operation including at least one temperature sensor disposed to measure a temperature of a preset battery cell among the plurality of battery cells for the plurality of respective trays; and a temperature calculation operation of calculating a temperature of each of the plurality of trays, based on a temperature measured by a temperature sensor unit.

The capacity consistency determination operation may be configured to include estimating a correction capacity for each of the plurality of battery cells for the plurality of respective trays by applying the charge capacity, the discharge capacity, and the temperature to each of the plurality of battery cells for the plurality of respective trays using the capacity correction formulas of the plurality of respective trays; and comparing the correction capacity with reference capacity range and determining whether each of the plurality of battery cells for the plurality of respective trays is good or bad based on a comparison result.

### BRIEF DESCRIPTION OF DRAWINGS

Certain aspects, features, and advantages of the present disclosure are illustrated by the following detailed description with reference to the accompanying drawings.

FIG. 1 is a block diagram schematically illustrating a device for testing a capacity of a battery cell according to an embodiment.

FIG. 2 is an illustrative diagram illustrating a capacity measurement unit.

FIG. 3 is an illustrative diagram illustrating a temperature acquisition unit.

FIG. 4 is an illustrative diagram illustrating the structure of a plurality of trays TR1 to TRm including a plurality of battery cells Ce1_1 to Ce1_n and Cem_1 to Cem_n.

FIG. 5 is an illustrative diagram illustrating the disposition of battery cells and temperature sensors included in a first tray.

FIG. 6 is an illustrative diagram illustrating an arrangement structure of a temperature sensor.

FIG. 7 is an illustrative diagram illustrating a capacity consistency determination unit.

FIG. 8 is a flowchart illustrating a method of testing a capacity of a battery cell according to an embodiment.

FIG. 9 is a flowchart illustrating a capacity consistency determination operation.

FIG. 10 is a block diagram of a computing device that may fully or partially implement a device and method for testing a capacity of a battery cell according to an embodiment.

### DETAILED DESCRIPTION

Features of the present disclosure disclosed in this patent document are described by example embodiments with reference to the accompanying drawings.

Hereinafter, embodiments will be further described with reference to detailed experimental examples. The embodiments and comparative examples included in the experimental examples are merely illustrative of the present disclosure and do not limit the scope of the appended claims. It is obvious to those skilled in the art that various changes and modifications to the embodiments are possible within the scope and technical idea of the present disclosure, and it is also natural that such changes and modifications fall within the scope of the appended claims.

The present disclosure may have various modifications and various embodiments, and specific embodiments are illustrated in the drawings and described in detail. However, this is not intended to limit the present disclosure to specific embodiments, and it should be understood that all modifications, equivalents, or substitutes included in the scope and idea of the present disclosure are included.

The terms first, second, etc. may be used to describe various components, but the components should not be limited by the terms. The terms are used only for the purpose of distinguishing one component from another. For example, without departing from the scope of the present disclosure, a first component may be referred to as a second component, and similarly, a second component may also be referred to as a first component. The term “and/or” includes a combination of a plurality of related described items or any of a plurality of related described items.

The terms used in this application are used only to describe specific embodiments and are not intended to limit the present disclosure. The singular expression includes the plural expression unless the context clearly indicates otherwise. In this application, the terms “includes”, “has” and the like are intended to specify the presence of a feature, number, step, operation, component, part, or combination thereof described in the specification, but should be understood not to preclude the possibility of the presence or addition of one or more other features, numbers, steps, operations, components, parts, or combinations thereof.

Unless otherwise defined, all terms used herein, including technical or scientific terms, have the same meaning as commonly understood by one of ordinary skill in the art to which this disclosure belongs. Terms defined in commonly used dictionaries should be interpreted as having a meaning consistent with the meaning they have in the context of the relevant technology, and shall not be interpreted in an ideal or overly formal sense unless explicitly defined in this application.

Hereinafter, with reference to the attached drawings, embodiments will be described in more detail.

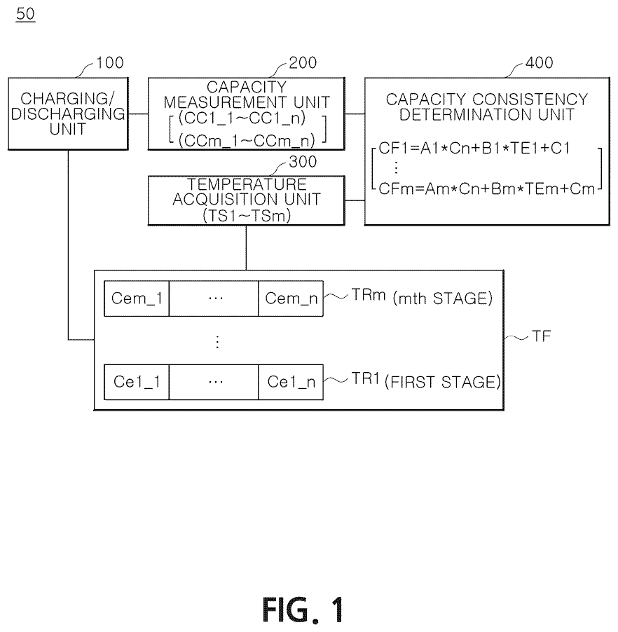

FIG. 1 is a block diagram schematically illustrating the configuration of a device for testing a capacity of a battery cell according to an embodiment.

Referring to FIG. 1, a device 50 for testing a capacity of a battery cell according to an embodiment may include a charging/discharging unit 100, a capacity measurement unit 200, a temperature acquisition unit 300, and a capacity consistency determination unit 400.

For example, the charging/discharging unit 100 may perform charging and discharging on a plurality of battery cells Ce1_1 to Ce1_n and Cem_1 to Cem_n (where n is a natural number of 2 or more) respectively included in a plurality of trays TR1 to TRm (where m is a natural number of 2 or more).

For example, the charging/discharging unit 100 may charge the plurality of respective battery cells Ce1_1 to Ce1_n and Cem_1 to Cem_n respectively included in the plurality of trays TR1 to TRm using a preset charging current. Furthermore, the charging/discharging unit 100 may discharge a plurality of respective battery cells Ce1_1 to Ce1_n and Cem_1 to Cem_n respectively included in the plurality of trays TR1 to TRm using a preset discharging current. For example, the charging/discharging unit 100 may include a charger that generates a charge current and a discharger that generates a discharge current. For example, the charger may be implemented as a constant current and/or a constant voltage circuit, and the discharger may be implemented using a discharge resistor and a relay.

For example, the capacity measurement unit 200 may measure the charge capacities CC1_1 to CC1_n and CCm_1 to CCm_n and discharge capacities DC1_1 to DC1_n and DCm_1 to DCm_n for the plurality of respective battery cells Ce1_1 to Ce1_n and Cem_1 to Cem_n based on the charge current and discharge current of the charging/discharging unit 100.

For example, the capacity measurement unit 200 may measure the charge capacities CC1_1 to CC1_n and CCm_1 to CCm_n for the plurality of respective battery cells Ce1_1 to Ce1_n and Cem_1 to Cem_n by multiplying the charge current and charging time. For example, the plurality of battery cells Ce1_1 to Ce1_n and Cem_1 to Cem_n may respectively have the same charge current, but the charge time may vary depending on the state of health (SOH) of the corresponding battery cell, resulting in different charge capacities.

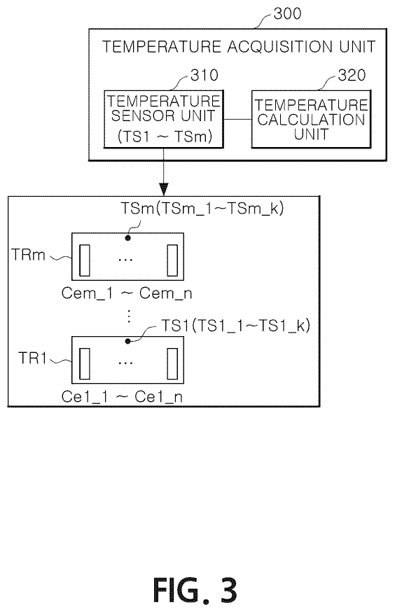

Furthermore, as an example, the capacity measurement unit 200 may measure the discharge capacities DC1_1 to DC1_n and DCm_1 to DCm_n of the plurality of respective battery cells Ce1_1 to Ce1_n and Cem_1 to Cem_n using the discharge current and discharge time. For example, the plurality of battery cells Ce1_1 to Ce1_n and Cem_1 to Cem_n may respectively have the same discharge current, but the discharge time may vary depending on the state of health (SOH) of the corresponding battery cell, resulting in different discharge capacities. The capacity measurement unit 200 is further described with reference to FIG. 3.

For example, the temperature acquisition unit 300 may acquire temperatures TE1 to TEm for the plurality of respective trays TR1 to TRm using the temperature of at least one battery cell among the plurality of battery cells Ce1_1 to Ce1_n and Cem_1 to Cem_n. For example, the temperature acquisition unit 300 may measure the temperature of at least one battery cell among the plurality of battery cells Ce1_1 to Ce1_n and Cem_1 to Cem_n based on the temperature measured by each temperature sensor disposed therein. The temperature sensor is described with reference to FIG. 3.

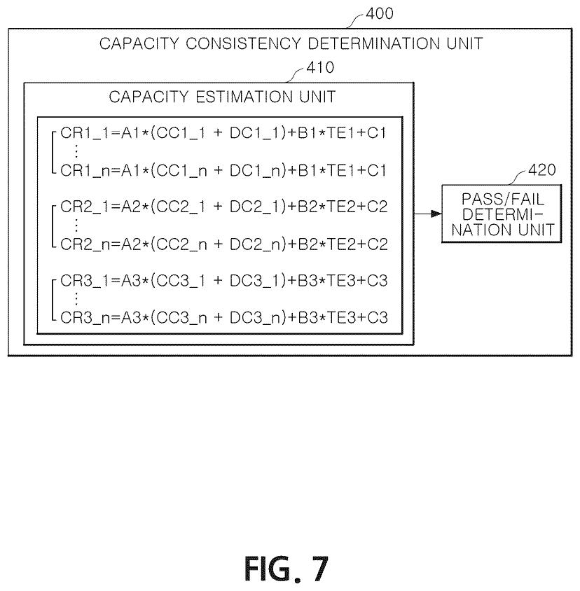

In addition, for example, the capacity consistency determination unit 400 may estimate correction capacities CR1_1 to CR1_n and CRm_1 to CRm_n for the plurality of respective battery cells Ce1_1 to Ce1_n and Cem_1 to Cem_n using different capacity correction formulas CR1 to CRm predetermined for the plurality of respective trays TR1 to TRm, based on the charge capacities CC1_1 to CC1_n and CCm_1 to CCm_n, the discharge capacities DC1_1 to DC1_n and DCm_1 to DCm_n and the temperatures TE1 to TEm, and may determine capacity consistency for each of the plurality of battery cells Ce1_1 to Ce1_n and Cem_1 to Cem_n based on the correction capacities CR1_1 to CR1_n and CRm_1 to CRm_n. The capacity consistency determination unit 400 is further described with reference to FIG. 7.

In the present disclosure, the charging/discharging unit 100, the capacity measurement unit 200, the temperature acquisition unit 300, and the capacity consistency determination unit 400 may respectively be implemented as individual processors or a single processor, without being particularly limited to any one thereof. Furthermore, the charging/discharging unit 100, the capacity measurement unit 200, the temperature acquisition unit 300, and the capacity consistency determination unit 400 may respectively be implemented as hardware element(s), software element(s), or a combination thereof in at least one integrated circuit Ic embedded in a device for testing a capacity of a battery cell, without being particularly limited to any one thereof.

Meanwhile, the device 50 for testing a capacity of a battery cell according to an embodiment may be implemented in a battery management system (BMS).

For example, the battery management system (BMS) may include at least one processor, in which case the at least one processor may execute at least one command stored in internal or external memory to perform a capacity inspection operation on a battery cell.

A battery module or battery device including a battery cell of an embodiment may be applied to pouch cells, cylindrical cells, prismatic cells, and the like.

The battery cell or battery module in the present disclosure may be widely applied in green technology fields such as means of transportation such as electric vehicles or drones, battery charging stations, and other solar and wind power generation utilizing batteries. Furthermore, the battery cell or battery module in the present disclosure may be used in eco-friendly electric vehicles, hybrid vehicles, and the like to ameliorate the effects of climate change by reducing air pollution and greenhouse gas emissions.

For respective drawings of 41 the present disclosure, unnecessarily redundant descriptions of identical reference numerals and components with identical functions may be omitted, and possible differences may be described for respective drawings.

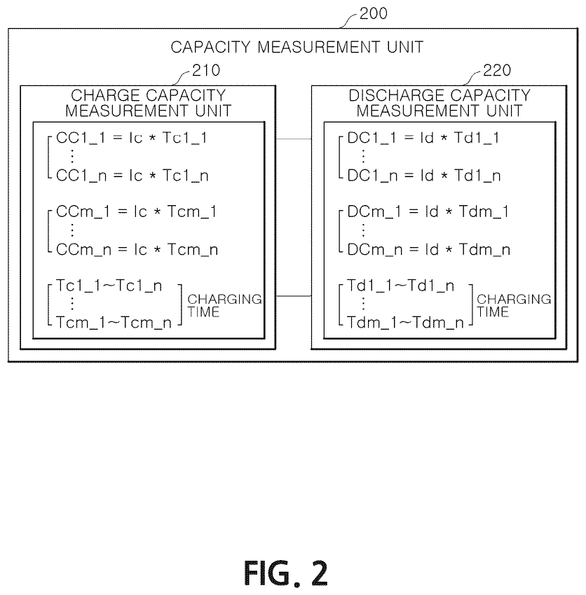

FIG. 2 is an illustrative diagram of a capacity measurement unit.

Referring to FIG. 2, the capacity measurement unit 200 may include a charge capacity measurement unit 210 and a discharge capacity measurement unit 220.

For example, the charge capacity measurement unit 210 may measure the charge capacities CC1_1 to CC1_n and CCm_1 to CCm_n for the plurality of respective battery cells Ce1_1 to Ce1_n and Cem_1 to Cem_n for the plurality of respective trays TR1 to TRm based on the charge current Ic and charging times Tc1_1 to Tc1_n and Tcm_1 to Tcm_n provided by the charging/discharging unit 100.

For example, as illustrated in FIG. 2, the charge capacities CC1_1 to CC1_n and CCm_1 to CCm_n may respectively be obtained by multiplying the charge current Tc by the charge times Tc1_1 to Tc1_n and Tcm_1 to Tcm_n.

For example, the discharge capacity measurement unit 220 may measure the discharge capacities DC1_1 to DC1_n and DCm_1 to DCm_n for the plurality of respective battery cells Ce1_1 to Ce1_n and Cem_1 to Cem_n for the plurality of respective trays TR1 to TRm, based on the discharge current Id and discharge times Td1_1 to Td1_n and Tdm 1 to Tdm_n by the charging/discharging unit 100.

For example, as illustrated in FIG. 2, the discharge capacities DC1_1 to DC1_n and DCm_1 to DCm_n may respectively be obtained by multiplying the discharge current Td by the discharge times Td1_1 to Td1_n and Tdm 1 to Tdm n.

FIG. 3 is an illustrative diagram of a temperature acquisition unit.

Referring to FIG. 3, the temperature acquisition unit 300 may include a temperature sensor unit 310 and a temperature calculation unit 320.

For example, the temperature sensor unit 310 may include at least one or more temperature sensors TS1 to TSm configured to measure the temperature of a preset battery cell among the plurality of battery cells Ce1_1 to Ce1_n and Cem_1 to Cem_n for the plurality of respective trays TR1 to TRm. For example, the plurality of trays TR1 to TRm may respectively include a plurality of temperature sensors TS1_1 to TS1_5 and TSm_1 to TSm_5.

For example, the temperature calculation unit 320 may calculate temperatures TE1 to TEm for the plurality of respective trays TR1 to TRm based on the temperatures measured by the temperature sensor unit 310.

For example, it may be assumed that the tray in the present disclosure includes a first tray TR1 of a first stage and an mth tray TRm of an mth stage, the first tray TR1 includes a plurality of battery cells Ce1_1 to Ce1_n, and the mth tray TRm includes a plurality of battery cells Cem_1 to Cem_n.

For example, one temperature sensor TS1 may be disposed on one battery cell among the plurality of battery cells Ce1_1 to Ce1_n, and one temperature sensor TSm may be disposed on one battery cell among the plurality of battery cells Cem_1 to Cem_n. The temperature TEL sensed by the temperature sensor TS1 may be determined as the temperature for the first tray TR1, and the temperature TEm sensed by the temperature sensor TSm may be determined as the temperature for the mth tray TRm.

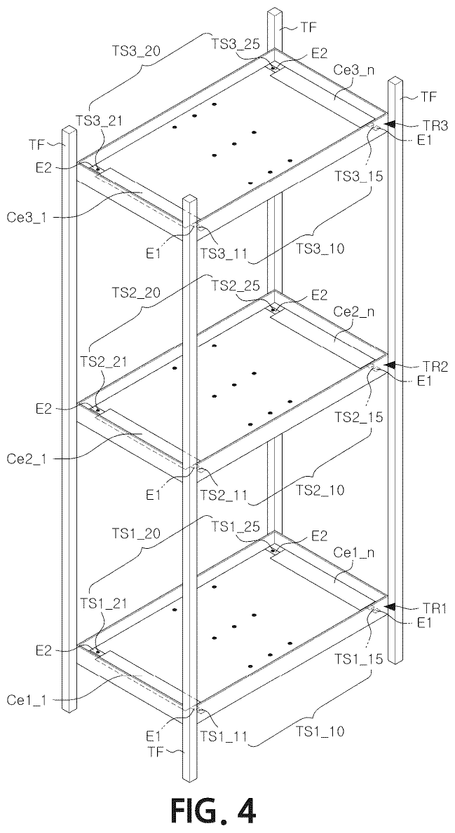

As another example, among a plurality of battery cells Ce1_1 to Ce1_n, a plurality of temperature sensors TS1_1 to TS1_k (where k is a natural number of 2 or more and n or less) may be disposed for a plurality of battery cells, and among a plurality of battery cells Cem_1 to Cem_n, a plurality of temperature sensors TSm_1 to TSm-k may be disposed for a plurality of battery cells. The average temperature of the temperatures TE1_1 to TE1_k sensed by the temperature sensors TS1_1 to TS1_k may be determined as the temperature for the first tray TR1, and the average temperature of the temperatures TEm_1 to TEm-k sensed by the temperature sensors TSm_1 to TSm-k may be determined as the temperature for the mth tray TRm. The temperature acquisition unit 300 will be further described with reference to FIGS. 4 to 6.

FIG. 4 is an illustrative diagram showing the structure of a plurality of trays TR1 to TRm including a plurality of battery cells Ce1_1 to Ce1_n and Cem_1 to Cem_n.

Referring to FIG. 4, in the trays TR1 to TRm of the present disclosure, a tray structure with m=3 is described, in which a first tray TR1 is disposed at the first stage, a second tray TR2 is disposed at the second stage, and a third tray TR3 is disposed at the third stage.

For example, the first to third trays TR1 to TR3 may be supported by a tray frame TF. The first tray TR1 may include a plurality of battery cells Ce1_1 to Ce1_n, the second tray TR2 may include a plurality of battery cells Ce2_1 to Ce2_n, and the third tray TR3 may include a plurality of battery cells Ce3_1 to Ce3_n.

For example, a plurality of battery cells Ce1_1 to Ce1_n included in the first tray TR1 may be disposed in a row such that a plurality of cathodes E1 are adjacent to each other and a plurality of anodes E2 are adjacent to each other. Furthermore, as another example, the temperature sensor unit 310 may include temperature sensors TS1_11 to TS1_15 disposed at equal intervals on the plurality of cathodes E1 of the plurality of battery cells Ce1_1 to Ce1_n, and temperature sensors TS1_21 to TS1_25 disposed at equal intervals on the plurality of anodes E2 of the plurality of battery cells Ce1_1 to Ce1_n.

In addition, for example, a plurality of battery cells Ce2_1 to Ce2_n included in the second tray TR2 may be disposed in a row such that a plurality of cathodes E1 are adjacent to each other and a plurality of anodes E2 are adjacent to each other. For example, the temperature sensor unit 310 may include temperature sensors TS2_11 to TS2_15 disposed at equal intervals on a plurality of cathodes E1 of a plurality of battery cells Ce2_1 to Ce2_n, and temperature sensors TS2_21 to TS2_25 disposed at equal intervals on a plurality of anodes E2 of a plurality of battery cells Ce2_1 to Ce2_n.

In addition, for example, a plurality of battery cells Ce3_1 to Ce3_n included in the third tray TR3 may be disposed in a row such that a plurality of cathodes E1 are adjacent to each other and a plurality of anodes E2 are adjacent to each other. For example, the temperature sensor unit 310 may include temperature sensors TS3_11 to TS3_15 disposed at equal intervals on the plurality of cathodes E1 of the plurality of battery cells Ce3_1 to Ce3_n, and temperature sensors TS3_21 to TS3_25 disposed at equal intervals on the plurality of anodes E2 of the plurality of battery cells Ce3_1 to Ce3_n.

In the example illustrated in FIG. 4, each tray contains a total of ten temperature sensors, including five temperature sensors disposed on the cathode and five temperature sensors disposed on the anode. However, this is merely an example for convenience of explanation and understanding, and is not intended to be limiting.

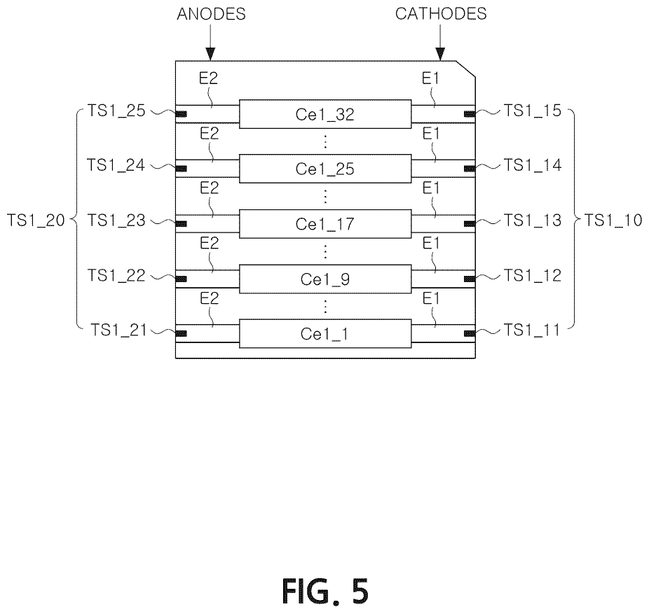

FIG. 5 illustrates an example of the disposition of battery cells and temperature sensors included in the first tray.

Referring to FIG. 5, for example, if 32 battery cells Ce1_1 to Ce1_32 are included in the first tray TR1 and the temperature sensors are disposed at intervals of 8 battery cells, the temperature sensor unit 310 may include temperature sensors TS1_11, TS1_12, TS1_13, TS1_14 and TS1_15 disposed on the respective cathodes E1 of the first, ninth, seventeenth, twenty-fifth, and thirty-second battery cells Ce1_1, Ce1-9, Ce1_17, Ce1_25 and Ce1_32, and temperature sensors TS1_21, TS1_22, TS1_23, TS1_24 and TS1_25 disposed on the anodes E2.

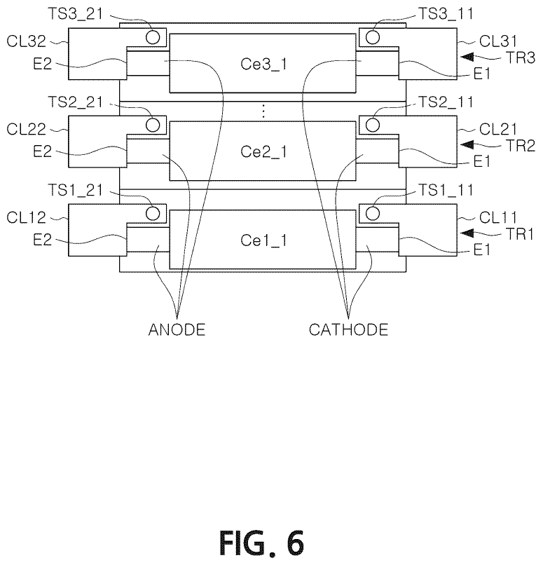

FIG. 6 is an illustrative diagram illustrating an arrangement structure of a temperature sensor.

Referring to FIG. 6, the arrangement structure of the temperature sensor will be further described. A charging clip CL11 and a discharging clip CL12 for charging and discharging may be attached to the cathode E1 and the anode E2 of the first battery cell Ce1_1 included in the first tray TR1. Temperature sensors TS1_11 and TS1_21 may be disposed on the charging clip CL11 and the discharging clip CL12, respectively. Accordingly, the temperature sensors TS1_11 and TS1_21 may detect temperatures of the respective cathode E1 and anode E2 of the first battery cell Ce1_1.

FIG. 7 is an illustrative diagram of a capacity consistency determination unit.

Referring to FIG. 7, the capacity consistency determination unit 400 may include a capacity estimation unit 410 and a pass/fail determination unit 420.

For example, the capacity estimation unit 410 may estimate the correction capacities CR1_1 to CR1_n and CRm_1 to CRm_n for the plurality of respective battery cells Ce1_1 to Ce1_n and Cem_1 to Cem_n for the plurality of respective trays TR1 to TRm by applying the charge capacities CC1_1 to CC1_n and CCm_1 to CCm_n, the discharge capacities DC1_1 to DC1_n and DCm_1 to DCm_n, and the temperatures TE1 to TEm to the plurality of respective trays TR1 to TRm using the capacity correction formulas for the plurality of respective trays TR1 to TRm.

For example, the first to third capacity correction formulas CR1, CR2 and CR3 for the first to third trays TR1 to TR3 may be expressed as in Formula 1, Formula 2, and Formula 3 below.

$$CR 1 : CR1\_n = A 1 * ( CC1\_n + DC1\_n ) + B 1 * TE 1 + C 1 \qquad [ Formula 1 ]$$

$$CR 2 : CR2\_n = A 2 * ( CC2\_n + DC2\_n ) + B 2 * TE 2 + C 2 \qquad [ Formula 2 ]$$

$$CR 3 : CR3\_n = A 3 * ( CC3\_n + DC3\_n ) + B 3 * TE 3 + C 3 \qquad [ Formula 3 ]$$

In Formulas 1, 2, and 3, CR1_n, CR2_n, and CR3_n represent the correction capacities for the first to third trays TR1 to TR3, and n is 2 or more and a natural number corresponding to a plurality of battery cells. For the first tray TR1, A1 represents the capacity constant, B1 represents the temperature constant, C1 represents a general constant, and TE1 represents the temperature. For the second tray TR2, A2 is the capacity constant, B2 is the temperature constant, C2 is a general constant, and TE2 is the temperature. For the third tray TR3, A3 is the capacity constant, B3 is the temperature constant, C3 is a general constant, and TE3 is the temperature.

Meanwhile, while the present disclosure provides examples of the first tray TR1 to the third tray TR3, these are merely examples for explanation and understanding and are not intended to be limiting.

For example, using the first capacity correction formula (CR1_1~n) for the first tray TR1, the correction capacities CR1_1 to CR1_n for the plurality of battery cells Ce1_1 to Ce1_n may be expressed as shown in Formula 4 below.

$$CR1\_ 1 = A 1 * ( CC1\_ 1 + DC1\_ 1 ) + B 1 * TE 1 + C 1 \qquad [ Formula 4 ]$$

$$CR1\_n = A 1 * ( CC1\_n + DC1\_n ) + B 1 * TE 1 + C 1$$

In Formula 4, CC1_1 and DC1_1 represent the charge capacity and discharge capacity for battery cell Ce1_1, and CC1_n and DC1_n represent the charge capacity and discharge capacity for battery cell Ce1_n.

For example, using the second capacity correction formula CR2_n for the second tray TR2, the correction capacities CR2_1 to CR2_n for the plurality of battery cells Ce2_1 to Ce2_n may be expressed as shown in Formula 5 below.

$$CR2\_ 1 = A 2 * ( CC2\_ 1 + DC2\_ 1 ) + B 2 * TE 2 + C 2 \qquad [ Formula 5 ]$$

$$CR2\_n = A 2 * ( CC2\_n + DC2\_n ) + B 2 * TE 2 + C 2$$

In Formula 5, CC2_1 and DC2_1 represent the charge capacity and discharge capacity for battery cell Ce2_1, and CC2_n and DC2_n represent the charge capacity and discharge capacity for battery cell Ce2_n.

For example, using the third capacity correction formula CR3_n for the third tray TR3, the correction capacities CR3_1 to CR3_n for the plurality of battery cells Ce3_1 to Ce3_n may be expressed as shown in Formula 6 below.

$$CR3\_ 1 = A 3 * capacity ( CC3\_ 1 + DC3\_ 1 ) + B 3 * temperature TE 3 + C 3 \qquad [ Formula 6 ]$$

$$CR3\_n = A 3 * capacity ( CC3\_n + DC3\_n ) + B 3 * temperature ( TE 3 ) + C 3$$

In Formula 6, CC2_1 and DC2_1 represent the charge capacity and discharge capacity for battery cell Ce2_1, and CC3_n and DC3_n represent the charge capacity and discharge capacity for battery cell Ce3_n.

For example, the pass/fail determination unit 420 compares the correction capacities CR1_1 to CR1_n and CRm_1 to CRm_n with a preset reference capacity range Cref1 to Cref2. Based on this comparison, the pass/fail determination unit may determine whether each of the plurality of battery cells Ce1_1 to Ce1_n and Cem_1 to Cem_n for the plurality of respective trays TR1 to TRm is a good or bad product.

For example, by comparing each of the correction capacities CR1_1 to CR1_n and CRm_1 to CRm_n with the reference capacity range Cref1 to Cref2, any of the correction capacities fall within the reference capacity range Cref1 to Cref2, the corresponding battery cell may be determined as a good product. If any of the correction capacities fall below or exceed the reference capacity range Cref1 to Cref2, the corresponding battery cell may be determined as a bad product.

Accordingly, the capacity of the battery cell may be predicted more accurately, and furthermore, false defects and true defects of the battery cells may be clearly identified, thereby preventing the outflow of true defects and thus enabling the production of high-quality battery cells overall.

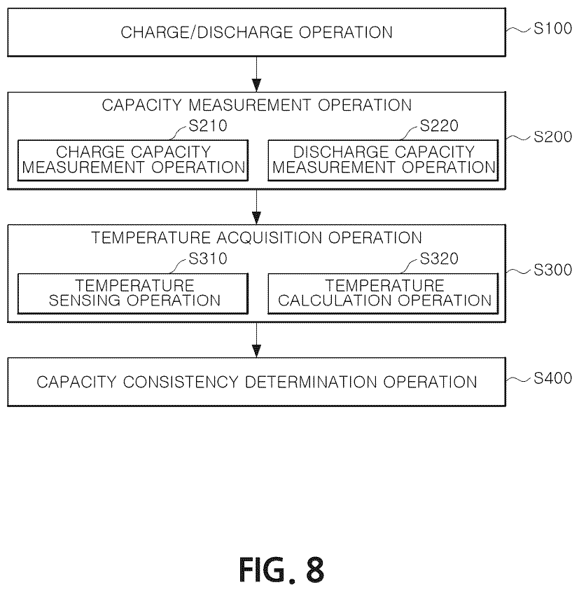

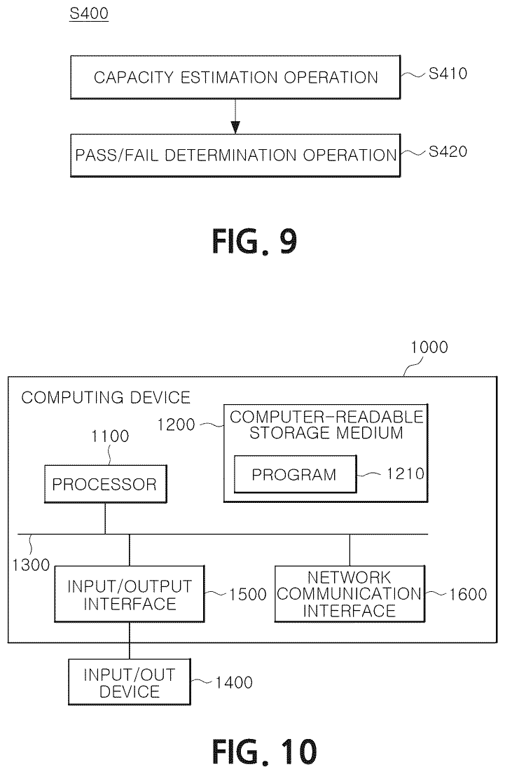

Hereinafter, a method of testing a capacity of a battery cell will be described with reference to FIGS. 8 and 9. In the present disclosure, the description of the method of testing a capacity of a battery cell and the description of the device for testing a capacity of a battery cell may be complementary or applicable in common, unless mutually exclusive. Accordingly, overlapping descriptions may be omitted. Below, the main processes of the method of testing a capacity of a battery cell will be described.

FIG. 8 is a flowchart illustrating a method of testing a capacity of a battery cell according to an embodiment.

Referring to FIG. 8, a method of testing a capacity of a battery cell according to an embodiment may be performed by the device 50 for testing a capacity battery cell illustrated in FIG. 1. The method of testing a capacity of a battery cell according to an embodiment may a include charge/discharge operation S100, a capacity measurement operation S200, a temperature acquisition operation S300, and a capacity consistency determination operation S400.

For example, in the charge/discharge operation S100, the device 50 for testing a capacity of a battery cell (see FIG. 1) may perform charging and discharging on a plurality of battery cells Ce1_1 to Ce1_n and Cem_1 to Cem_n respectively included in a plurality of trays TR1 to TRm.

For example, in the capacity measurement operation S200, the device 50 for testing a capacity of a battery cell (see FIG. 1) may measure the charge capacities CC1_1 to CC1_n and CCm_1 to CCm_n and discharge capacities DC1_1 to DC1_n and DCm_1 to DCm_n for the plurality of respective battery cells Ce1_1 to Ce1_n and Cem_1 to Cem_n based on the charge and discharge currents generated by the charging/discharging unit 100.

For example, in the temperature acquisition operation S300, the device 50 for testing a capacity of a battery cell (see FIG. 1) may obtain the temperatures TE1 to TEm for the respective plurality of trays TR1 to TRm using the temperature of at least one battery cell among the plurality of battery cells Ce1_1 to Ce1_n and Cem_1 to Cem_n.

In addition, for example, in the capacity consistency determination operation S400, the device 50 for testing a capacity of a battery cell (see FIG. 1) may estimate correction capacities CR1_1 to CR1_n and CRm_1 to CRm_n for the plurality of respective battery cells Ce1_1 to Ce1_n and Cem_1 to Cem_n using different capacity correction formulas CR1 to CRm (see Formula 1 to Formula 3) predetermined for a plurality of respective trays TR1 to TRm based on the charge capacities CC1_1 to CC1_n and CCm_1 to CCm_n, the discharge capacities DC1_1 to DC1_n and DCm_1 to DCm_n and the temperatures TE1 to TEm, and may determine capacity consistency for each of the plurality of battery cells Ce1_1 to Ce1_n and Cem_1 to Cem_n based on the correction capacities CR1_1 to CR1_n and CRm_1 to CRm_n.

Referring to FIG. 8, the capacity measurement operation S200 may include at least one of a charge capacity measurement operation S210 and a discharge capacity measurement operation S220.

For example, in the charge capacity measurement operation S210, the device 50 for testing a capacity of a battery cell (see FIG. 1) may measure the charge capacities CC1_1 to CC1_n and CCm_1 to CCm_n for the plurality of respective battery cells Ce1_1 to Ce1_n and Cem_1 to Cem_n for the plurality of respective trays TR1 to TRm, based on the charge current provided by the charging/discharging unit 100.

In addition, for example, in the discharge capacity measurement operation S220, the device 50 for testing a capacity of a battery cell (see FIG. 1) may measure the discharge capacities DC1_1 to DC1_n and DCm_1 to DC for the plurality of respective battery cells Ce1-1 to Ce1-n and Cem-1 to Cem-n for the respective trays TR1 to TRm based on the discharge current from the charging/discharging unit 100.

Furthermore, referring to FIG. 8, the temperature acquisition operation S300 may include at least one of a temperature sensing operation S310 and a temperature calculation operation S320.

For example, in the temperature sensing operation S310, the device 50 for testing a capacity of a battery cell (see FIG. 1) may include at least one temperature sensor disposed to measure the temperature of a preset battery cell among the plurality of battery cells Ce1-1 to Ce1-n and Cem-1 to Cem-n for the plurality of respective trays TR1 to TRm.

Furthermore, for example, in the temperature calculation operation S320, the device 50 for testing a capacity of a battery cell (see FIG. 1) may calculate the temperatures TE1 to TEm for the plurality of respective trays TR1 to TRm based on the temperature measured by the temperature sensor unit 310.

FIG. 9 is a flowchart illustrating the capacity consistency determination operation.

Referring to FIG. 9, the capacity consistency determination operation S400 may include a capacity estimation operation S410 and a pass/fail determination operation S420.

For example, in the capacity estimation operation S410, the device 50 for testing a capacity of a battery cell (see FIG. 1) may estimate the correction capacities CR1-1 to CR1-n and CRm-1 to CRm-n for the plurality of respective battery cells Ce1-1 to Ce1-n and Cem-1 to Cem-n for the plurality of respective trays TR1 to TRm by applying the charge capacities CC1-1 to CC1-n and CCm-1 to CCm-n, the discharge capacities DC1-1 to DC1-n and DCm-1 to DCm-n, and the temperatures TE1 to TEm for the plurality of respective battery cells Ce1-1 to Ce1-n and Cem-1 to Cem-n for the plurality of respective trays TR1 to TRm using the capacity correction formulas CR1 to CRm.

For example, in the pass/fail determination operation S420, the device 50 for testing a capacity of a battery cell (see FIG. 1) may compare the correction capacities CR1-1 to CR1-n and CRm-1 to CRm-n with a preset reference capacity range Cref1 to Cref2, and based on the comparison result, may determine whether each of the plurality of battery cells Ce1-1 to Ce1-n and Cem-1 to Cem-n for the plurality of respective trays TR1 to TRm is good or bad.

FIG. 10 is a block diagram of a computing device that may fully or partially implement a device and method for testing a capacity of a battery cell according to an embodiment.

As illustrated in FIG. 10, a computing device 1000 includes at least one of at least one processor 1100, a computer-readable storage medium 1200, and a communication bus 1300.

The processor 1100 may enable the computing device 1000 to operate according to the above-mentioned example embodiments. For example, the processor 1100 may execute one or more programs stored in the computer-readable storage medium 1200. The one or more programs may include one or more computer executable instructions, and the computer-executable instructions may be configured to enable the computing device 1000 to execute operations according to example embodiments, when executed by the processor 1100.

The computer-readable storage medium 1200 is configured to store computer-executable instructions or program code, program data, and/or other suitable forms of information. The program 1210 stored in the computer-readable storage medium 1200 includes a set of instructions executable by the processor 1100. In an embodiment, the computer-readable storage medium 1200 may be a memory (a volatile memory, such as random access memory, a non-volatile memory, or an appropriate combination thereof), one or more magnetic disk storage devices, optical disk storage devices, flash memory devices, other types of storage media that may be accessed by the computing device 1000 and store required information, or a suitable combination thereof.

The communication bus 1300 interconnects various other components of computing device 1000, including processor 1100 and computer-readable storage medium 1200.

The computing device 1000 may also include one or more input/output interfaces 1500 and one or more network communication interfaces 1600 that provide an interface for one or more input/output devices 1400. The input/output interface 1500 and the network communication interface 1600 are connected to the communication bus 1300. The network may be any one of cellular networks such as Global System for Mobile Communications (GSM), Enhanced Data Rates for GSM Evolution (EDGE), General Packet Radio Service (GPRS), Code Division Multiple Access (CDMA), Time Division-CDMA (TD-CDMA), Universal Mobile Telecommunications System (UMTS), Long Term Evolution (LTE), or other cellular networks.

The input/output device 1400 may be connected to other components of the computing device 1000 through the input/output interface 1500. Examples of the input/output device 1400 may include a pointing device (such as a mouse or trackpad), keyboard, touch input device (such as a touchpad or touchscreen), or voice or sound input device, input devices such as various types of sensor devices and/or imaging devices, and/or output devices such as display devices, printers, speakers, and/or network cards. The illustrative input/output device 1400 may be included within the computing device 1000 as a component constituting the computing device 1000, or may be connected to the computing device 1000 as a separate device distinct from the computing device 1000.

Meanwhile, in embodiments of the present disclosure, a program for performing the methods described in this specification on a computer, and a computer-readable recording medium containing the program, may be included. The computer-readable recording medium may include program instructions, local data files, local data structures, and the like, singly or in combination. The media may be those specifically designed and constructed for the present disclosure, or may be those commonly available in the computer software field. Examples of computer-readable recording media may include magnetic media such as hard disks, floppy disks, and magnetic tapes, optical recording media such as CD-ROM and DVD, a specially configured hardware device to store and perform program instructions, such as ROM, RAM, flash memory, and the like. Examples of the programs may include not only machine language code such as that produced by a compiler, but also high-level language code that may be executed by a computer using an interpreter or the like.

As set forth above, according to an aspect of the present disclosure, in the process of measuring and correcting capacity during charging and discharging of a battery cell, a pre-prepared correction formula may be applied to each of a plurality of trays including a plurality of battery cells, thereby providing an effect of more accurately estimating the capacity.

Only specific examples of implementations of certain embodiments are described. Variations, improvements and enhancements of the disclosed embodiments and other embodiments may be made based on the disclosure of this patent document.

What is claimed is:

1. A device for testing a capacity of a battery cell, comprising:
a charging/discharging unit charging and discharging a plurality of battery cells included in each of a plurality of trays;
a capacity measurement unit measuring a charge capacity and a discharge capacity of each of the plurality of battery cells based on a charge current and a discharge current of the charging/discharging unit;
a temperature acquisition unit acquiring a temperature of each of the plurality of trays using a temperature of at least one battery cell among the plurality of battery cells; and
a capacity consistency determination unit estimating a correction capacity for each of the plurality of battery cells, based on the charge capacity, the discharge capacity, and the temperature, and using different capacity correction formulas predetermined for the plurality of respective trays, and determining capacity consistency for each of the plurality of battery cells based on the correction capacity.

2. The device of claim 1, wherein the capacity measurement unit includes,
a charge capacity measurement unit measuring the charge capacity of each of the plurality of battery cells for the plurality of respective trays, based on the charge current from the charging/discharging unit; and
a discharge capacity measurement unit measuring the discharge capacity of each of the plurality of battery cells for the plurality of respective trays, based on the discharge current from the charging/discharging unit.

3. The device of claim 1, wherein the temperature acquisition unit includes,
a temperature sensor unit including at least one temperature sensor disposed to measure a temperature of a preset battery cell among the plurality of battery cells for the plurality of respective trays; and
a temperature calculation unit calculating a temperature of each of the plurality of trays, based on a temperature measured by the temperature sensor unit.

4. The device of claim 1, wherein the capacity consistency determination unit includes,
a capacity estimation unit estimating a correction capacity for each of the plurality of battery cells for the plurality of respective trays by applying the charge capacity, the discharge capacity, and the temperature to each of the plurality of battery cells for the plurality of respective trays using the capacity correction formulas for the plurality of respective trays; and
a pass/fail determination unit comparing the correction capacity with a preset reference capacity range and determining whether each of the plurality of battery cells for the plurality of respective trays is good or bad based on a comparison result.

5. A method of testing a capacity of a battery cell, comprising:
charging and discharging a plurality of battery cells included in each of a plurality of trays;
measuring a charge capacity and a discharge capacity of each of the plurality of battery cells based on a charge current and a discharge current of a charging/discharging unit;
acquiring a temperature of each of the plurality of trays using a temperature of at least one battery cell among the plurality of battery cells; and
a capacity consistency determination operation of estimating a correction capacity of each of the plurality of battery cells based on the charge capacity, the discharge capacity, and the temperature, and using different capacity correction formulas predetermined for the plurality of respective trays, and determining capacity consistency of each of the plurality of battery cells based on the correction capacity.

6. The method of claim 5, wherein the measuring the charge capacity and the discharge capacity includes at least one of,
a charge capacity measurement operation of measuring the charge capacity of each of the plurality of battery cells for the plurality of respective trays, based on the charge current from the charging/discharging unit; and
a discharge capacity measurement operation of measuring the discharge capacity of each of the plurality of battery cells for the plurality of respective trays, based on the discharge current from the charging/discharging unit.

7. The method of claim 5, wherein the acquiring the temperature includes at least one of,
a temperature sensing operation including at least one temperature sensor disposed to measure a temperature of a preset battery cell among the plurality of battery cells for the plurality of respective trays; and
a temperature calculation operation of calculating a temperature of each of the plurality of trays, based on a temperature measured by a temperature sensor unit.

8. The method of claim 5, wherein the capacity consistency determination operation includes,
estimating a correction capacity for each of the plurality of battery cells for the plurality of respective trays by applying the charge capacity, the discharge capacity, and the temperature to each of the plurality of battery cells for the plurality of respective trays using the capacity correction formulas of the plurality of respective trays; and
comparing the correction capacity with a preset reference capacity range and determining whether each of the plurality of battery cells for the plurality of respective trays is good or bad based on a comparison result.
